(19) United States
(12) Patent Application Publication
(10) Pub. No.: US 2023/0411580 A1
(43) Pub. Date: Dec. 21, 2023

(54) DISPLAY DEVICE AND METHOD OF MANUFACTURING THE SAME

(71) Applicant: Samsung Display Co., LTD., Yongin-si (KR)

(72) Inventors: Seung Min SONG, Yongin-si (KR); Jin Sun KIM, Yongin-si (KR); Sae Hee RYU, Yongin-si (KR); Il YOU, Yongin-si (KR); Seung Min LEE, Yongin-si (KR); Kwang Young CHOI, Yongin-si (KR)

(73) Assignee: Samsung Display Co., LTD., Yongin-si (KR)

(21) Appl. No.: 18/337,902

(22) Filed: Jun. 20, 2023

(30) Foreign Application Priority Data
Jun. 21, 2022 (KR) 10-2022-0075809

(51) Int. Cl. H01L 33/62; H01L 25/075; H01L 25/16

(52) U.S. Cl. CPC H01L 33/62; H01L 25/0753; H01L 25/167; H01L 2933/0066

(57) ABSTRACT

A display device includes: a first base layer including opening; a pad layer disposed on the first base layer, the pad layer overlapping the opening; a second base layer disposed on the pad layer; a pixel circuit layer disposed on the second base layer; and light emitting elements disposed on the pixel circuit layer, the light emitting elements connected to the pixel circuit layer and included in pixels. A color of the first base layer is different from a color of the second base layer.

### CROSS-REFERENCE TO RELATED APPLICATION(S)

This application claims priority to and benefits of Korean patent application No. 10-2022-0075809 under 35 U.S.C. § 119(a), filed on Jun. 21, 2022, in the Korean Intellectual Property Office (KIPO), the entire contents of which are incorporated herein by reference.

### BACKGROUND

### 1. Technical Field

Embodiments relate to a display device and a method of manufacturing the display device.

### 2. Description of the Related Art

Recently, as interest in information displays is increased, research and development of display devices have been continuously conducted.

### SUMMARY

Embodiments provide a display device capable of determining an etch rate (or etching defect) in real time by providing a first base layer and a second base layer that have different colors.

Embodiments also provide a method of manufacturing the display device.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include: a first base layer including opening; a pad layer disposed on the first base layer, the pad layer overlapping the opening; a second base layer disposed on the pad layer; a pixel circuit layer disposed on the second base layer; and light emitting elements disposed on the pixel circuit layer, the light emitting elements connected to the pixel circuit layer and included in pixels, wherein a color of the first base layer may be different from a color of the second base layer.

The first base layer may include: a first sub-base layer; and a second sub-base layer disposed on the first sub-base layer, the second sub-base layer being closer to the pad layer than the first sub-base layer. A light transmittance of the second sub-base layer may be lower than a light transmittance of the first sub-base layer.

The first sub-base layer, the second sub-base layer, and the second base layer may include polyimide.

The second sub-base layer may have a color darker than colors of the first sub-base layer and the second base layer.

A thickness of the second sub-base layer may be about 1/50 or less of a thickness of the first sub-base layer.

The first base layer and the second base layer may include a same material.

A light transmittance of the first base layer may be lower than a light transmittance of the second base layer.

The first base layer and the second base layer may include polyimide.

The display device may further include: a chip on film (COF) electrically connected to the pad layer, the chip on film (COF) extending onto a surface of the first base layer; and a driving chip provided on the chip on film (COF), the driving chip that provides a signal to the pixel circuit layer. In a plan view, the chip on film (COF) and the driving chip may overlap a display area in which the pixels are disposed.

The pixel circuit layer may include a lower connection electrode disposed on the second base layer, the lower connection electrode connected to the pad layer and penetrating the second base layer.

The lower connection electrode may be electrically connected to a signal line of the pixel circuit layer through a contact hole.

The display device may further include: a first barrier layer disposed directly on the first base layer, the first barrier layer having a contact hole overlapping the opening of the first base layer; and a second barrier layer disposed between the first barrier layer and the second base layer. The pad layer may be disposed between the first barrier layer and the second barrier layer. The pad layer may be electrically connected to the chip on film (COF) through the contact hole of the first base layer.

The first barrier layer and the second barrier layer may include an inorganic insulating material.

In accordance with another aspect of the present disclosure, there is provided a method of manufacturing a display device, the method including: forming a pad layer on a first base layer; forming a second base layer including a contact hole on the first base layer on which the pad layer is formed; forming, on the second base layer, a pixel circuit layer including a lower connection electrode in contact with the pad layer through the contact hole of the second base layer; forming a display element layer including light emitting elements on the pixel circuit layer; and removing a portion of the first base layer to expose the pad layer, wherein a color of the first base layer is different from a color of the second base layer.

The forming of the pad layer on the first base layer may include: coating, on a first sub-base layer, a second sub-base layer having a light transmittance lower than a light transmittance of the first sub-base layer; forming a first barrier layer on the second sub-base layer; patterning the pad layer on the first barrier layer; and forming a second barrier layer covering the pad layer on the first barrier layer. The first sub-base layer, the second sub-base layer, and the second base layer may include polyimide.

The second sub-base layer may have a color darker than colors of the first sub-base layer and the second base layer.

The removing of the portion of the first base layer may include: etching the first base layer overlapping the pad layer by using at least one of a laser etching process and an atmospheric pressure plasma treatment; and determining whether the etching of the first base layer is completed based on an image of an etched area in which the first base layer is etched.

The determining of whether the etching of the first base layer is completed may include: comparing the image of the etched area with a reference value; additionally etching the first base layer in case that clarity of a pad layer of the image of the etched area is lower than the reference value; and ending the etching of the first base layer in case that the clarity of the pad layer of the image of the etched area is not lower than the reference value.

The method may further include: forming a connection line in contact with the pad layer; and disposing a chip on film (COF) connected to the connection line on a surface of the first base layer.

The chip on film (COF) may overlap a display area in which pixels including the light emitting elements are disposed.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it may be the only element between the two elements, or one or more intervening elements may also be present. Like reference numerals refer to like elements throughout.

FIG. 1 is a schematic perspective view schematically illustrating a light emitting element in accordance with embodiments.

FIG. 2 is a schematic sectional view illustrating an example of the light emitting element of FIG. 1.

FIGS. 3 and 4 are schematic plan views illustrating a display device in accordance with embodiments.

FIG. 5 is a schematic plan view illustrating an example of a sub-pixel included in the display device of FIG. 3.

FIG. 6 is a schematic sectional view illustrating an example taken along line I-I′ of FIG. 5.

FIG. 7 is a schematic sectional view illustrating an example of a pixel included in the display device of FIG. 3.

FIG. 8 is a schematic sectional view illustrating an example of a portion of the display device of FIG. 3.

FIG. 9 is a schematic sectional view illustrating an example of the portion of the display device of FIG. 3.

FIG. 10 is a schematic sectional view illustrating an example of the portion of the display device of FIG. 3.

FIGS. 11 to 21 are schematic views illustrating a method of manufacturing the display device in accordance with embodiments.

FIG. 22 is a schematic plan view illustrating a tiled display device including the display device in accordance with embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

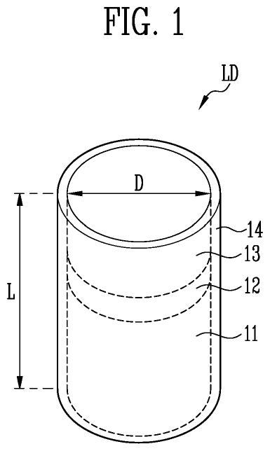

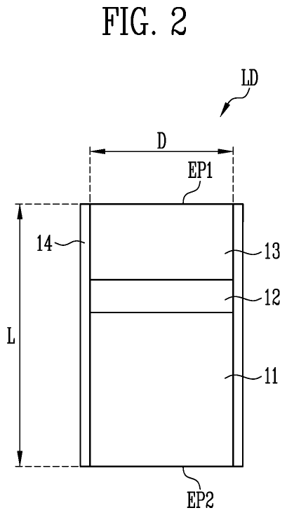

FIG. 1 is a schematic perspective view schematically illustrating a light emitting element in accordance with embodiments. FIG. 2 is a schematic sectional view illustrating an example of the light emitting element of FIG. 1.

Referring to FIGS. 1 and 2, the light emitting element LD may include a first semiconductor layer 11, a second semiconductor layer 13, and an active layer 12 disposed between the first and second semiconductor layers 11 and 13. In an example, the light emitting element LD may be implemented as a light emitting stack structure (or stack pattern) in which the first semiconductor layer 11, the active layer 12, and the second semiconductor layer 13 are sequentially stacked.

The light emitting element LD may be formed in a shape extending in a direction (e.g., a stack direction). In case that an extending direction of the light emitting element LD is a length direction, the light emitting element LD may include a first end portion EP1 and a second end portion EP2 along the length direction. One semiconductor layer selected from the first semiconductor layer 11 and the second semiconductor layer 13 may be positioned at the first end portion EP1 of the light emitting element LD, and the other semiconductor layer selected from the first semiconductor layer 11 and the second semiconductor layer 13 may be positioned at the second end portion EP2 of the light emitting element LD.

The light emitting element LD may be formed in various shapes. In an example, the light emitting element LD may have a rod-like shape, a bar-like shape, a pillar-like shape, or the like, which is long in its length direction (i.e., its aspect ratio is greater than 1) as shown in FIG. 1. In another example, the light emitting element LD may have a rod-like shape, a bar-like shape, a pillar-like shape, or the like, which is short in its length direction (i.e., its aspect ratio is smaller than 1). In still another example, the light emitting element LD may have a rod-like shape, a bar-like shape, a pillar-like shape, or the like, of which aspect ratio is 1.

The light emitting element LD may include, for example, a light emitting diode (LED) manufactured small enough to have a diameter D and/or a length L to a degree of a nano scale (or nanometers) to a micro scale (micrometers).

In case that the light emitting element LD is long in its length direction (i.e., its aspect ratio is greater than 1), the diameter D of the light emitting element LD may be in a range of about 0.5 μm to about 6 μm, and the length L of the light emitting element LD may be in a range of about 1 μm to about 10 μm. However, the diameter D and the length L of the light emitting element LD are not limited thereto, and the size of the light emitting element LD may be changed to accord with requirement conditions (or design conditions) of a lighting device or a self-luminous display device, to which the light emitting element LD is applied.

The first semiconductor layer 11 may include, for example, at least one n-type semiconductor layer. The first semiconductor layer 11 may include an upper surface in contact with the active layer 12 and a lower surface exposed to the outside along the length direction of the light emitting element LD. The lower surface of the first semiconductor layer 11 may be an end portion (e.g., bottom end portion) of the light emitting element LD.

The active layer 12 may be formed on the first semiconductor layer 11, and may be formed in a single or multiple quantum well structure. In an example, in case that the active layer 12 is formed in the multiple quantum well structure, a barrier layer, a strain reinforcing layer, and a well layer, which constitute one unit, may be periodically and repeatedly stacked in the active layer 12. The strain reinforcing layer may have a lattice constant smaller than that of the barrier layer, to further reinforce strain, e.g., compressive strain applied to the well layer. However, the structure of the active layer 12 is not limited to the above-described embodiment.

The active layer 12 may emit light having a wavelength of 400 nm to 900 nm, and use a double hetero structure. The active layer 12 may include a first surface in contact with the first semiconductor layer 11 and a second surface in contact with the second semiconductor layer 13.

In an embodiment, a color (e.g., light output color) of the light emitting element LD may be determined according to a wavelength of light emitted from the active layer 12. The color of the light emitting element LD may determine a color of a pixel corresponding thereto. For example, the light emitting element LD may emit red light, green light, or blue light.

In case that an electric field having a voltage or more is applied to the end portions (e.g., opposite end portions) of the light emitting element LD, the light emitting element LD may emit light as electron-hole pairs are combined in the active layer 12. The light emission of the light emitting element LD may be controlled by using such a principle, so that the light emitting element LD may be used as a light source (e.g., light emitting source) for various light emitting devices, including a pixel of a display device.

The second semiconductor layer 13 may be formed on the second surface of the active layer 12, and may include a semiconductor layer having a type different from that of the first semiconductor layer 11.

The second semiconductor layer 13 may include a lower surface in contact with the second surface and an upper surface exposed to the outside along the length direction of the light emitting element LD. The upper surface of the second semiconductor layer 13 may be another end portion (e.g., top end portion) of the light emitting element LD.

In an embodiment, the first semiconductor layer 11 and the second semiconductor layer 13 may have different thicknesses in the length direction of the light emitting element LD. In an example, the first semiconductor layer 11 may have a thickness relatively thicker than that of the second semiconductor layer 13 along the length direction of the light emitting element LD. Accordingly, the active layer 12 of the light emitting element LD may be positioned more adjacent (or closer) to the upper surface of the second semiconductor layer 13 than the lower surface of the first semiconductor layer 11.

Although it is illustrated that each of the first semiconductor layer 11 and the second semiconductor layer 13 is formed as a single layer, embodiments are not limited thereto. In an embodiment, each of the first semiconductor layer 11 and the second semiconductor layer 13 may further include at least one layer, e.g., a clad layer and/or a Tensile Strain Barrier Reducing (TSBR) layer according to the material of the active layer 12. The TSBR layer may be a strain reducing layer disposed between semiconductor layers having different lattice structures to perform a buffering function for reducing a lattice constant difference. The TSBR may be formed as a p-type semiconductor layer such as p-GAInP, p-AlInP or p-AlGaInP, but embodiments are not limited thereto.

In some embodiments, the light emitting element LD may further include a contact electrode (hereinafter, referred to as a “first contact electrode”) disposed on the top (or upper surface) of the second semiconductor layer 13, in addition to the first semiconductor layer 11, the active layer 12, and the second semiconductor layer 13, which are described above. In another example, the light emitting element LD may further include another contact electrode (hereinafter, referred to as a “second contact electrode”) disposed at an end of the first semiconductor layer 11.

Each of the first and second contact electrodes may be an ohmic contact electrode, but embodiments are not limited thereto. In some embodiments, each of the first and second contact electrodes may be a Schottky contact electrode. The first and second contact electrodes may include a conductive material.

In an embodiment, the light emitting element LD may further include an insulative film 14 (or insulating film). However, in some embodiments, the insulative film 14 may be omitted, and be provided to cover only portions of the first semiconductor layer 11, the active layer 12, and the second semiconductor layer 13.

The insulative film 14 may prevent an electrical short circuit which occurs in case that the active layer 12 is in contact with a conductive material in addition to the first semiconductor layer 11 and the second semiconductor layer 13. For example, the insulative film 14 may minimize a surface defect of the light emitting element LD, thereby improving the lifetime and light emission efficiency of the light emitting element LD. For example, in case that emitting elements LD are densely disposed, the insulative film 14 may prevent an unwanted short circuit which occurs between the light emitting elements LD. Whether the insulative film is provided is not limited as long as the active layer 12 may prevent occurrence of a short circuit with external conductive material.

The insulative film 14 may be formed in a shape entirely surrounding an outer circumference of the light emitting stack structure including the first semiconductor layer 11, the active layer 12, and the second semiconductor layer 13.

Although a case where the insulative film 14 is formed in a shape entirely surrounding an outer circumference of each of the first semiconductor layer 11, the active layer 12, and the second semiconductor layer 13 is described in the above-described embodiment, embodiments are not limited thereto.

The insulative film 14 may include a transparent insulating material. For example, the insulative film 14 may include at least one insulating material selected from the group consisting of silicon oxide (SiOₓ), silicon nitride (SiNₓ), silicon oxynitride (SiOₓN_{y}), aluminum oxide (AlOₓ), titanium dioxide (TiO₂), hafnium oxide (HfOₓ), titanium strontium oxide (SrTiOₓ), cobalt oxide (CoₓO_{y}), magnesium oxide (MgO), zinc oxide (ZnO), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InxOy:H, niobium oxide (NbₓO_{y}), magnesium fluoride (MgFₓ), aluminum fluoride (AlFₓ), Alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), vanadium nitride (VN), and the like. However, embodiments are not limited thereto, and various materials having insulating properties may be used as the material of the insulative film 14.

The insulative film 14 may be formed as a single layer or as a multi-layer including at least two layers.

In some embodiments, the light emitting element LD may be implemented in a light emitting pattern having a core-shell structure. The first semiconductor layer 11 may be positioned at a core, e.g., in the middle portion (or center portion) of the light emitting element LD, the active layer 12 may be provided and/or formed in a shape surrounding the outer circumference of the first semiconductor layer 11, and the second semiconductor layer 13 may be provided and/or formed in a shape surrounding the active layer 12. For example, the light emitting element LD may further include a contact electrode surrounding at least one side of the second semiconductor layer 13. In some embodiments, the light emitting element LD may further include an insulative film which is provided on the outer circumference of the light emitting pattern having the core-shell structure and includes a transparent insulating material. The light emitting element LD implemented in the light emitting pattern having the core-shell structure may be manufactured through a growth process.

The above-described light emitting element LD may be used as a light emitting source (or light source) for various display devices. The light emitting element LD may be manufactured through a surface treatment process. For example, in case that light emitting elements LD are mixed in a liquid solution (e.g., solvent) to be supplied to each pixel area (e.g., an emission area of each pixel or an emission area of each sub-pixel), each light emitting element LD may be surface-treated such that the light emitting elements LD may not be unequally condensed in the solution but equally dispersed in the solution.

A light emitting unit (or light emitting device) including the above-described light emitting element LD may be used in various types of devices that require a light source, including a display device. In case that light emitting elements LD are disposed in an emission area of each pixel of a display panel, the light emitting elements LD may be used as a light source of the pixel. However, the application field of the light emitting element LD is not limited thereto. For example, the light emitting element LD may be used for other types of electronic devices that require a light source, such as a lighting device.

However, this is merely illustrative, and a light emitting element applied to display devices in accordance with embodiments is not limited thereto. For example, the light emitting element may be a flip chip type micro light emitting diode or an organic light emitting element including an organic emitting layer.

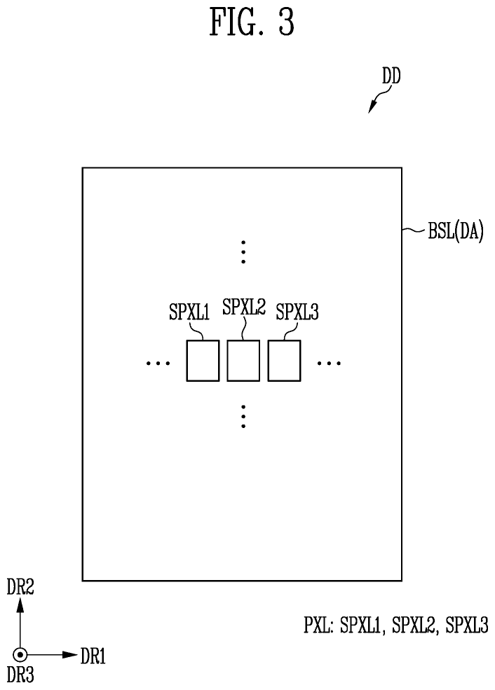

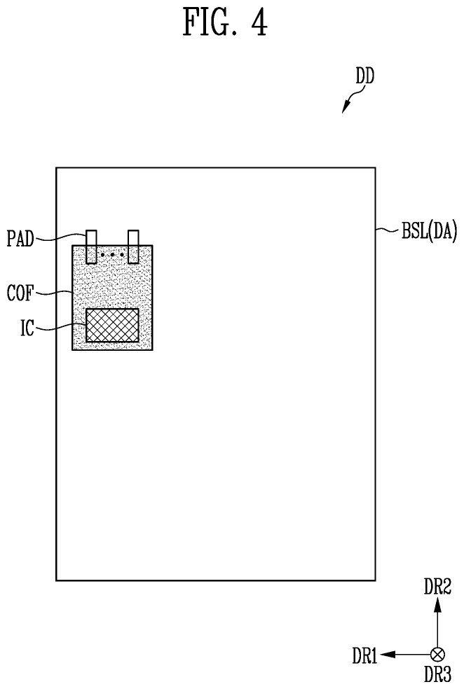

FIGS. 3 and 4 are schematic plan views illustrating a display device in accordance with embodiments.

Referring to FIGS. 3 and 4, the display device DD may include a base layer BSL and pixels PXL disposed on the base layer BSL. For example, the display device DD may further include a driver for driving the pixels PXL and a line part connecting the pixels PXL and the driver to each other.

In an embodiment, FIG. 4 schematically illustrates a planar shape of a rear surface (or back surface) of the display device DD. Pads PAD may be disposed in a rear surface of the base layer BSL, and the display device DD may further include a driving chip IC as the driver and a chip on film COF connecting (e.g., electrically connecting) the driving chip IC and the pads PAD to each other.

The display device DD may include a display area DA. In embodiments, the display device DD may include a chip on film COF and a driving chip IC, which overlap the display area DA, on the rear surface of the base layer BSL so as to minimize or remove a non-display area at an outer portion of the display area DA (i.e., so as to implement a zero-bezel). However, this is merely illustrative, and the display device DD may further include a non-display area surrounding at least a portion of the display area DA.

The base layer BSL may form a base member of the display device DD. The base layer BSL may be a rigid or flexible substrate or film. The base layer BSL may include layers. In an embodiment, the base layer BSL may have a structure in which a first base layer, barrier layers, and a second base layer are sequentially stacked. For example, the pads PAD may be included in the base layer BSL. As a partial configuration of the base layer BSL is removed (or etched), the pads PAD may be exposed to be connected (e.g., electrically connected) to the chip on film COF.

The display area DA may be an area in which the pixel PXL (i.e., sub-pixels SPXL1, SPXL2, and SPXL3 each including a light emitting element and a pixel circuit) is disposed. The pixels PXL may be arranged in a first direction DR1 and a second direction DR2. The pixels PXL may display an image in a third direction DR3.

In an embodiment, the pixel PXL may include a first sub-pixel SPXL1, a second sub-pixel SPXL2, and a third sub-pixel SPXL3. For example, the first sub-pixel SPXL1, the second sub-pixel SPXL2, and the third sub-pixel SPXL3 in the pixel PXL may be arranged in the first direction DR1. However, this is merely illustrative, and the arrangement direction of the sub-pixels in the pixel PXL is not limited thereto.

The first sub-pixel SPXL1, the second sub-pixel SPXL2, and the third sub-pixel SPXL3 may emit light of different colors. For example, the first sub-pixel SPXL1 may emit red light, the second sub-pixel SPXL2 may emit green light, and the third sub-pixel SPXL3 may emit blue light. However, this is merely illustrative, and the colors, kind, and number of sub-pixels constitute the pixel PXL are not limited thereto.

Each of the first sub-pixel SPXL1, the second sub-pixel SPXL2, and the third sub-pixel SPXL3 may be connected (e.g., electronically connected) to a scan line and a data line.

The scan line may be connected (e.g., electronically connected) to a scan driver. The scan driver may be included in the driving chip IC or be provided separately from the chip on film COF.

The data line may be connected (e.g., electronically connected) to a data driver. The data driver may be included in the driving chip IC.

The pads PAD may be connected (e.g., electrically connected) to the chip on film COF and the driving chip IC. For example, a data signal output from the data driver in the driving chip IC may be provided to the data line through the chip on film COF and the pads PAD.

In an embodiment, in a plan view, the pads PAD may overlap the display area DA. For example, the pads PAD may overlap an area in which the pixel PXL is disposed (or defined).

The chip on film COF may provide an area in which the driving chip IC is disposed. For example, the driving chip IC may be directly or indirectly mounted on the chip on film COF. An electrical signal provided by the driving chip IC may be supplied to the pixel PXL through a chip on film COF.

The number of chip on films COF is not limited. For example, the number of chip on films COF may be one or more. At least a portion of the chip on film COF may be disposed in the display area DA.

In some embodiments, the chip on film COF may include an insulating film and lines provided on the insulating film. The chip on film COF generally refers to a form in which an insulating film configured as a thin film and lines on the insulating film are formed, and may be designated as a tape carrier package, a flexible printed circuit board, or the like.

The driving chip IC may be disposed in the display area DA. A position of the driving chip IC may overlap the chip on film COF. The driving chip IC may be disposed on the rear surface (or lower surface) of the base layer BSL. Thus, the non-display area may be minimized.

In an embodiment, the driving chip IC may include the data driver and/or a timing controller. The driving chip IC may output a data signal to the data line. In another example, the driving chip IC may control driving of the data driver and/or scan driver by using a signal applied from an external processor.

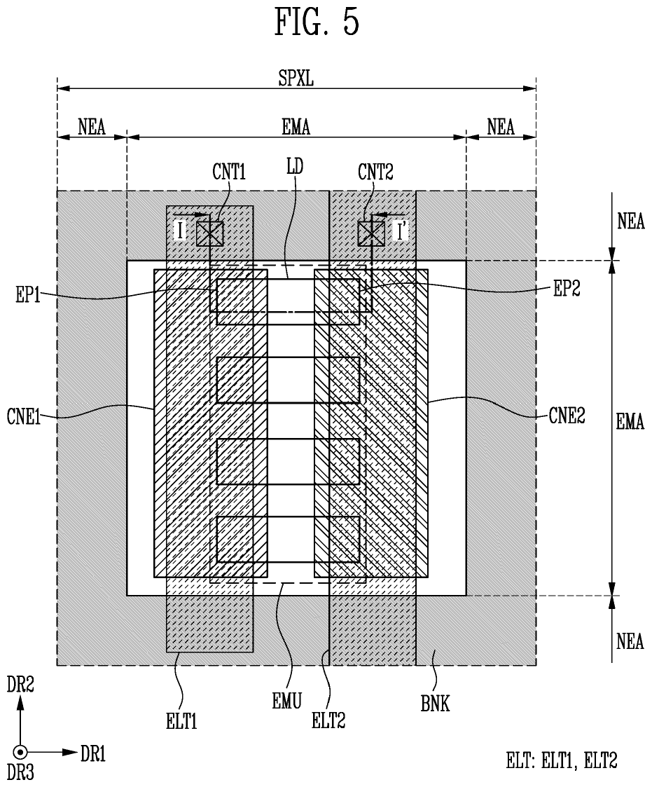

FIG. 5 is a schematic plan view illustrating an example of the sub-pixel included in the display device of FIG. 3.

Referring to FIGS. 3 and 5, the sub-pixel SPXL may include an emission area EMA and a non-emission area NEA. The sub-pixel SPXL may include a bank BNK, an alignment electrode ELT, light emitting elements LD, a first contact electrode CNE1, and a second contact electrode CNE2.

The sub-pixel SPXL may be one of the first sub-pixel SPXL1, the second sub-pixel SPXL2, and the third sub-pixel SPXL3.

The emission area EMA may overlap an opening defined by the bank BNK in a plan view. The light emitting elements LD may be disposed in the emission area EMA.

The light emitting elements LD may not be disposed in the non-emission area NEA. A portion of the non-emission area NEA may overlap the bank BNK in a plan view.

The bank BNK may have a shape protruding in a thickness direction of the base layer BSL (e.g., the third direction DR3), and have a form surrounding an area. Accordingly, an area, in which the bank BNK corresponding to the emission area EMA is not disposed, may be formed.

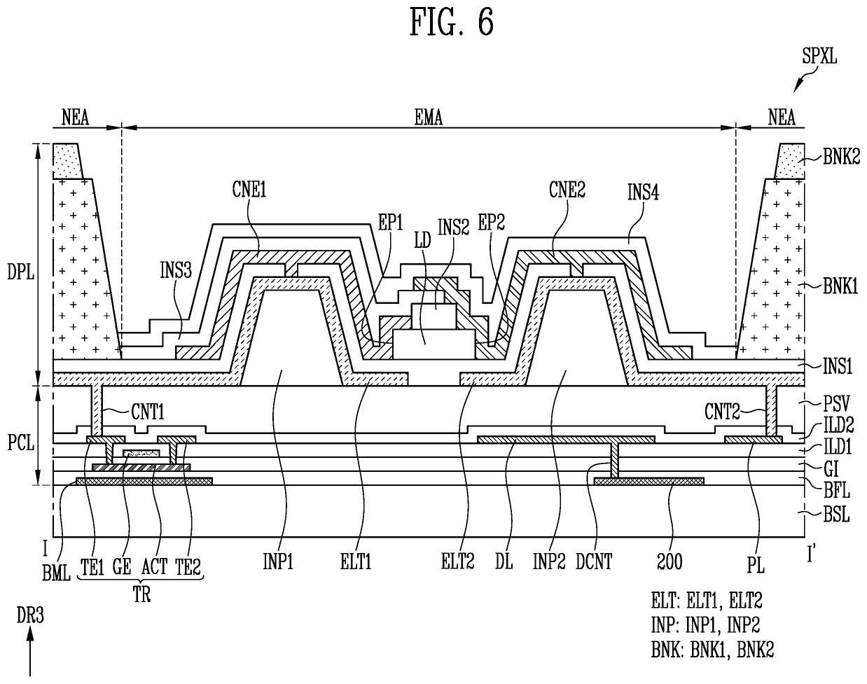

The bank BNK may form a space. The bank BNK may have a form surrounding a partial area in a plan view. The space may mean an area in which a fluid may be accommodated. In accordance with an embodiment, the bank BNK may include a first bank (see ‘BNK1’ of FIG. 6) and a second bank (see ‘BNK2’ of FIG. 6).

In accordance with an embodiment, an ink including the light emitting elements LD may be provided in a space defined by the bank BNK (e.g., the first bank BNK1), so that the light emitting elements LD may be disposed in the emission area EMA.

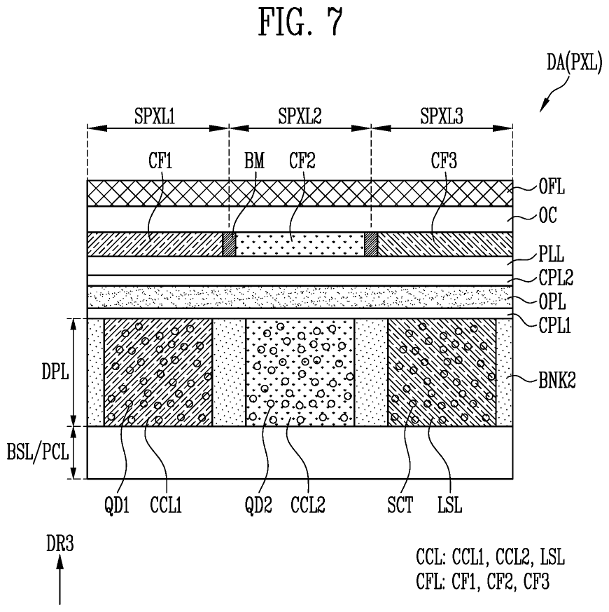

In accordance with an embodiment, a color conversion layer (see ‘CCL’ of FIG. 7) may be disposed (or patterned) in a space defined by the bank BNK (e.g., the second bank BNK2).

The bank BNK may define the emission area EMA and the non-emission area NEA. The bank BNK may surround at least a portion of the emission area EMA in a plan view. For example, an area in which the bank BNK is disposed may be the non-emission area NEA. An area, in which the light emitting elements LD are disposed, and the bank BNK is not disposed, may be the emission area EMA.

The alignment electrode ELT may be an electrode for aligning the light emitting elements LD. In some embodiments, the alignment electrode ELT may include a first electrode ELT1 and a second electrode ELT2. The alignment electrode ELT may be designated as an “electrode” or “electrodes.”

The alignment electrode ELT may have a single layer structure or a multi-layer structure. For example, the alignment electrode ELT may include at least one reflective electrode layer including a reflective conductive material, and selectively further include at least one transparent electrode layer and/or at least one conductive capping layer. In some embodiments, the alignment electrode ELT may include at least one of silver (Al), magnesium (Mg), aluminum (Al), platinum (Pt), palladium (Pd), gold (Au), nickel (Ni), neodymium (Nd), iridium (Ir), chromium (Cr), titanium (Ti), and any alloy thereof. However, embodiments are not limited thereto, and the alignment electrode ELT may include at least one of various materials having reflexibility. However, embodiments are not limited thereto.

The light emitting element LD may be disposed on the alignment electrode ELT. In some embodiments, at least a portion of the light emitting element LD may be disposed between the first electrode ELT1 and the second electrode ELT2. The light emitting element LD may be aligned between the first electrode ELT1 and the second electrode ELT2. The light emitting elements LD may form (or constitute) a light emitting unit EMU. The light emitting unit EMU may mean a unit including adjacent light emitting elements LD.

In some embodiments, the light emitting elements LD may be aligned in various manners. For example, an embodiment in which the light emitting elements LD are aligned in parallel between the first electrode ELT1 and the second electrode ELT2 is illustrated in FIG. 5. However, embodiments are not limited thereto. For example, the light emitting elements LD may be aligned in a series or series/parallel hybrid structure, and the number of units connected in series and/or parallel is not limited.

The first electrode ELT1 and the second electrode ELT2 may be spaced apart from each other. For example, the first electrode ELT1 and the second electrode ELT2 may be space apart from each other along a first direction DR1 in the emission area EMA, and each of the first electrode ELT1 and the second electrode ELT2 may extend along a second direction DR2.

In accordance with an embodiment, the first electrode ELT1 and the second electrode ELT2 may be electrodes for aligning the light emitting elements LD. The first electrode ELT1 may be a first alignment electrode, and the second electrode ELT2 may be a second alignment electrode.

The first electrode ELT1 and the second electrode ELT2 may be respectively supplied (or provided) with a first alignment signal and a second alignment signal in a process of aligning the light emitting elements LD. For example, a first alignment signal may be applied to the first electrode ELT1, and a second alignment signal may be applied to the second electrode ELT2. The first alignment signal and the second alignment signal may have different waveforms, different potentials, and/or different phases. For example, the first alignment signal may be an alternating current (AC) signal, and the second alignment signal may be a ground signal. However, embodiments are not limited thereto. An electric field may be formed between (or on) the first electrode ELT1 and the second electrode ELT2, so that the light emitting elements LD may be aligned between the first electrode ELT1 and the second electrode ELT2, based on the electric field. For example, the light emitting elements LD may be moved (or rotated) by a force (a dielectrophoresis (DEP) force) according to the electric field to be aligned (or disposed) on the alignment electrode ELT.

The first electrode ELT1 may be connected (e.g., electrically connected) to a circuit element (e.g., a transistor TR of FIG. 6) through a first contact hole CNT1. For example, the first electrode ELT1 may be an anode electrode.

The second electrode ELT2 may be connected (e.g., electrically connected) to a power line (see ‘PL’ of FIG. 6) through a second contact hole CNT2. In some embodiments, the second electrode ELT2 may be a cathode electrode.

A first end portion EP1 of each of the light emitting element LD may be adjacent to (or in contact with) the first electrode ELT1, and a second end portion EP2 of each of the light emitting element LD may be adjacent to (or in contact with) the second electrode ELT2.

In an embodiment, the first end portion EP1 of each of the light emitting elements LD may be connected (e.g., electrically connected) to the first electrode ELT1 through the first contact electrode CNE1. In an embodiment, the first end portion EP1 of each of the light emitting elements LD may be connected (e.g., directly connected) to the first electrode ELT1. In an embodiment, the first end portion EP1 of each of the light emitting elements LD may be connected (e.g., electrically connected) to only the first contact electrode CNE1, and may not be connected (e.g., electronically connected) to the first electrode ELT1.

Similarly, the second end portion EP2 of each of the light emitting elements LD may be connected (e.g., electrically connected) to the second electrode ELT2 through the second contact electrode CNE2. In an embodiment, the second end portion EP2 of each of the light emitting elements LD may be connected (e.g., directly connected) to the second electrode ELT2. In an embodiment, the second end portion EP2 of each of the light emitting elements LD may be connected (e.g., electrically connected) to only the second contact electrode CNE2, and may not be connected (e.g., electronically connected) to the second electrode ELT2.

The first contact electrode CNE1 and the second contact electrode CNE2 may be respectively disposed on first end portions EP1 and second end portions EP2 of the light emitting elements LD.

The first contact electrode CNE1 may be disposed on the first end portions EP1 of the light emitting elements LD to be connected (e.g., electrically connected) to the first end portions EP1. In an embodiment, the first contact electrode CNE1 may be disposed on the first electrode ELT1 to be connected (e.g., electrically connected) to the first electrode ELT1. The first end portions EP1 of the light emitting elements LD may be connected (e.g., electrically connected) to the first electrode ELT1 through the first contact electrode CNE1.

The second contact electrode CNE2 may be disposed on the second end portions EP2 of the light emitting elements LD to be connected (e.g., electrically connected) to the second end portions EP2. In an embodiment, the second contact electrode CNE2 may be disposed on the second electrode ELT2 to be connected (e.g., electrically connected) to the second electrode ELT2. The second end portions EP2 of the light emitting elements LD may be connected (e.g., electronically connected) to the second electrode ELT2 through the second contact electrode CNE2.

FIG. 6 is a schematic sectional view illustrating an example taken along line I-I′ of FIG. 5. FIG. 7 is a schematic sectional view illustrating an example of the pixel included in the display device of FIG. 3.

Referring to FIGS. 3, 5, 6, and 7, the sub-pixel SPXL may include a pixel circuit layer PCL and a display element layer DPL. For example, the pixel PXL including the sub-pixel SPXL may further include an optical layer OPL and a color filter layer CFL, which are disposed above the display element layer DPL.

The base layer BSL may form a base member on which the sub-pixel SPXL is formed. The base layer BSL may provide an area on which the pixel circuit layer PCL and the display element layer DPL may be disposed.

The pixel circuit layer PCL may be disposed on the base layer BSL. The pixel circuit layer PCL may include a lower auxiliary electrode BML, a buffer layer BFL, a transistor TR, a gate insulating layer GI, a first interlayer insulating layer ILD1, a power line PL, a data line DL, a second interlayer insulating layer ILD2, and a protective layer PSV.

The lower auxiliary electrode BML may be disposed on the base layer BSL. The lower auxiliary electrode BML may function as a path through which an electrical signal is transferred. A portion of the lower auxiliary electrode BML may overlap the transistor TR.

The lower auxiliary electrode BML may include a lower connection electrode 200. The lower connection electrode 200 may be covered by the buffer layer BFL. In an embodiment, the lower connection electrode 200 may be connected (e.g., electronically connected) to the data line DL through a data contact hole DCNT. The data contact hole DCNT may be formed to penetrate the buffer layer BFL, the gate insulating layer GI, and the first interlayer insulating layer ILD1.

The buffer layer BFL may be disposed on the base layer BSL. The buffer layer BFL may cover the lower auxiliary electrode BML. The buffer layer BFL may prevent an impurity from being diffused or permeated from the outside. The buffer layer BFL may include at least one of silicon oxide (SiOₓ), silicon nitride (SiNₓ), silicon oxynitride (SiOₓN_{y}), aluminum oxide (AlOₓ), and titanium oxide (TiOₓ). However, embodiments are not limited thereto.

The transistor TR may be a thin film transistor. In accordance with an embodiment, the transistor TR may be a driving transistor. The transistor TR may be connected (e.g., electrically connected) to a light emitting element LD. The transistor TR may be connected (e.g., electrically connected) to a first end portion EP1 of the light emitting element LD.

The transistor TR may include an active layer ACT, a first transistor electrode TE1, a second transistor electrode TE2, and a gate electrode GE.

The active layer ACT may be a semiconductor layer. The active layer ACT may be disposed on the buffer layer BFL. The active layer ACT may include at least one selected from the group consisting of poly-silicon, Low Temperature Polycrystalline Silicon (LTPS), amorphous silicon, and an oxide semiconductor.

The active layer ACT may include a first contact region in contact with the first transistor electrode TE1 and a second contact region in contact with the second transistor electrode TE2. The first contact region and the second contact region may correspond to a semiconductor pattern doped with an impurity (or dopant). A region between the first contact region and the second contact region may be a channel region. The channel region may be an intrinsic semiconductor pattern undoped with the impurity.

The gate electrode GE may be disposed on the gate insulating layer GI. The gate electrode GE may overlap the channel region of the active layer ACT.

The gate insulating layer GI may be disposed on the buffer layer BFL. The gate insulating layer GI may cover the active layer ACT. The gate insulating layer GI may include at least one of silicon oxide (SiOₓ), silicon nitride (SiNₓ), silicon oxynitride (SiOₓN_{y}), aluminum oxide (AlOₓ), and titanium oxide (TiOₓ). However, embodiments are not limited thereto.

The first interlayer insulating layer ILD1 may be disposed on the gate insulating layer GI. The first interlayer insulating layer ILD1 may cover the gate electrode GE. The first interlayer insulating layer ILD1 may include at least one of silicon oxide (SiOₓ), silicon nitride (SiNₓ), silicon oxynitride (SiOₓN_{y}), aluminum oxide (AlOₓ), and titanium oxide (TiOₓ). However, embodiments are not limited thereto.

The first transistor electrode TE1 and the second transistor electrode TE2 may be disposed on the first interlayer insulating layer ILD1. The first transistor electrode TE1 may be in contact with the first contact region of the active layer ACT, and the second transistor electrode TE2 may be in contact with the second contact region of the active layer ACT. For example, the first transistor electrode TE1 may be a drain electrode (or source electrode), and the second transistor electrode TE2 may be a source electrode (or drain electrode).

The first transistor electrode TE1 may be connected (e.g., electrically connected) to a first electrode ELT1 through a first contact hole CNT1 penetrating the protective layer PSV and the second interlayer insulating layer ILD2.

In an embodiment, the power line PL may be disposed on the first interlayer insulating layer ILD1. For example, the power line PL, the data line DL, the first transistor electrode TE1, and the second transistor electrode TE2 may be disposed on the same layer (e.g., the first interlayer insulating layer ILD1), and may be formed of a same material. The power line PL may be connected (e.g., electrically connected) to a second electrode ELT2 through a second contact hole CNT2 penetrating the protective layer PSV and the second interlayer insulating layer ILD2. The power line PL may supply a power source or an alignment signal through the second electrode ELT2.

The data line DL may be disposed on the first interlayer insulating layer ILD1. For example, the data line DL, the power line PL, the first transistor electrode TE1, and the second transistor electrode TE2 may be disposed on the same layer, and may be formed of the same material. The data line DL may be connected (e.g., electrically connected) to the lower connection electrode 200 through the data contact hole DCNT.

The second interlayer insulating layer ILD2 may be disposed on the first interlayer insulating layer ILD1. The second interlayer insulating layer ILD2 may cover the first transistor electrode TE1, the second transistor electrode TE2, the data line DL, and the power line PL. The second interlayer insulating layer ILD2 may include at least one of silicon oxide (SiOₓ), silicon nitride (SiNₓ), silicon oxynitride (SiOₓN_{y}), aluminum oxide (AlOₓ), and titanium oxide (TiOₓ). However, embodiments are not limited thereto.

The protective layer PSV may be disposed on the second interlayer insulating layer ILD2. In some embodiments, the protective layer PSV may include an organic material to planarize a lower step difference. For example, the protective layer PSV may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the protective layer PSV may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The display element layer DPL may be disposed on the pixel circuit layer PCL. The display element layer DPL may include a first insulating layer INS1, an insulating pattern INP, an alignment electrode ELT, a bank BNK, the light emitting element LD, a second insulating layer INS2, a first contact electrode CNE1, a third insulating layer INS3, a second contact electrode CNE2, and a fourth insulating layer INS4.

The insulating pattern INP may be disposed on the protective layer PSV. The insulating pattern INP may have various shapes in some embodiments. In an embodiment, the insulating pattern INP may protrude in the third direction DR3. For example, the insulating pattern INP may be formed to have an inclined surface inclined at an angle with respect to the base layer BSL. However, embodiments are not limited thereto, and the insulating pattern INP may have a sidewall with a curved shape, a stepped shape, or the like. In an example, the insulating pattern INP may have a part having a semicircular shape, a semi-elliptical shape, or the like.

The insulating pattern INP may function to form a step difference such that light emitting elements LD may be readily aligned in an emission area. In some embodiments, the insulating pattern INP may be a definition wall.

In accordance with an embodiment, a portion of the alignment electrode ELT may be disposed over the insulating pattern INP. For example, the insulating pattern INP may include a first insulating pattern INP1 and a second insulating pattern INP2. The first electrode ELT1 may be disposed over the first insulating pattern INP1, and the second electrode ELT2 may be disposed over the second insulating pattern INP2. Therefore, a reflective wall may be formed over the insulating pattern INP. Accordingly, light emitted from the light emitting element LD is reused, so that the light emission efficiency of the display device DD (or the sub-pixel SPXL) may be improved.

The insulating pattern INP may include at least one organic material and/or at least one inorganic material. In an example, the insulating pattern INP may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the insulating pattern INP may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The alignment electrode ELT may be disposed on the protective layer PSV and/or the insulating pattern INP. In some embodiments, the alignment electrode ELT may be disposed on a rear surface (or lower surface) of the first insulating layer INS1. For example, the alignment electrode ELT may be disposed between the insulating pattern INP or the protective layer PSV and the first insulating layer INS1. For example, a surface of the alignment electrode ELT may be in contact with the first insulating layer INS1.

The first electrode ELT1 may be connected (e.g., electrically connected) to the light emitting element LD. The first electrode ELT1 may be connected (e.g., electrically connected) to the first contact electrode CNE1 through a contact hole formed in the first insulating layer INS1.

The second electrode ELT2 may be connected (e.g., electrically connected) to the light emitting element LD. The second electrode ELT2 may be connected (e.g., electrically connected) to the second contact electrode CNE2 through a contact hole formed in the first insulating layer INS1.

The first insulating layer INS1 may be disposed over the alignment electrode ELT. For example, the first insulating layer INS1 may cover the first electrode ELT1 and the second electrode ELT2.

The bank BNK may be disposed on the first insulating layer INS1. In some embodiments, the bank BNK may include a first bank BNK1 and a second bank BNK2.

The first bank BNK1 may be disposed on the first insulating layer INS1. The first bank BNK1 may define an emission area EMA and a non-emission area NEA.

The first bank BNK1 may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the first bank BNK1 may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The second bank BNK2 may be disposed on the first bank BNK1. A color conversion layer CCL may be provided in a space formed by the second bank BNK2.

The second bank BNK2 may include an organic material and/or an inorganic material, which is included in the first bank BNK1.

The light emitting element LD may be disposed on the first insulating layer INS1. In some embodiments, the light emitting element LD may emit light, based on electrical signals (e.g., an anode signal and a cathode signal) provided from the first contact electrode CNE1 and the second contact electrode CNE2.

The light emitting element LD may be disposed in an area surrounded by the first bank BNK1. The light emitting element LD may be disposed between the first insulating pattern INP1 and the second insulating pattern INP2.

The second insulating layer INS2 may be disposed on the light emitting element LD. The second insulating layer INS2 may cover an active layer of the light emitting element LD.

The second insulating layer INS2 may expose at least a portion of the light emitting element LD. For example, the first end portion EP1 and a second end portion EP2 of the light emitting element LD may be exposed from the second insulating layer INS2, and be connected (e.g., electrically connected) respectively to the first contact electrode CNE1 and the second contact electrode CNE2.

In case that the second insulating layer INS2 is formed on light emitting elements LD after the light emitting elements LD are aligned (e.g., completely aligned), the light emitting elements LD may be prevented from being separated from positions at which the light emitting elements LD are aligned.

The second insulating layer INS2 may have a single-layer structure or a multi-layer structure. The second insulating layer INS2 may include the above-described inorganic material. However, embodiments are not limited thereto.

The first contact electrode CNE1 and the second contact electrode CNE2 may be disposed on the first insulating layer INS1. The first contact electrode CNE1 may be connected (e.g., electrically connected) to the first end portion EP1 of the light emitting element LD. The second contact electrode CNE2 may be connected (e.g., electrically connected) to the second end portion EP2 of the light emitting element LD.

The first contact electrode CNE1 may be connected (e.g., electrically connected) to the first electrode ELT1 through a contact hole penetrating the first insulating layer INS1, and the second contact electrode CNE2 may be connected (e.g., electrically connected) to the second electrode ELT2 through a contact hole penetrating the first insulating layer INS1.

The first contact electrode CNE1 and the second contact electrode CNE2 may include a conductive material. For example, the first contact electrode CNE1 and the second contact electrode CNE2 may include a transparent conductive material including one of Indium Tin Oxide (ITO), Indium Zinc Oxide (IZO), and Indium Tin Zinc Oxide (ITZO).

The third insulating layer INS3 may be disposed on the second insulating reflective layer 140 and the first contact electrode CNE1. At least a portion of the third insulating layer INS3 may be disposed between the first contact electrode CNE1 and the second contact electrode CNE2, and accordingly, a short-circuit defect between the first contact electrode CNE1 and the second contact electrode CNE2 may be prevented.

The fourth insulating layer INS4 may be disposed on the third insulating layer INS3 and the second contact electrode CNE2. The fourth insulating layer INS4 may protect components of the display element layer DPL from external influence.

Each of the third insulating layer INS3 and the fourth insulating layer INS4 may have a single-layer structure or a multi-layer structure. The third insulating layer INS3 and the fourth insulating layer INS4 may include the above-described inorganic material.

FIG. 7 illustrates a configuration above the first bank BNK1 in the display area DA. As shown in FIG. 7, the second bank BNK2 may be disposed between first to third sub-pixels SPXL1, SPXL2, and SPXL3 or at a boundary of the first to third sub-pixels SPXL1, SPXL2, and SPXL3, and define a space (or area) overlapping each of the first to third sub-pixels SPXL1, SPXL2, and SPXL3. The space defined by the second bank BNK2 may be an area in which the color conversion layer CCL may be provided.

The color conversion layer CCL may be disposed above light emitting elements LD in the space surrounded by the second bank BNK2. In an embodiment, the color conversion layer CCL may include a first color conversion layer CCL1 corresponding to the first sub-pixel SPXL1, a second color conversion layer CCL2 corresponding to the second sub-pixel SPXL2, and a light scattering layer LSL corresponding to the third sub-pixel SPXL3.

The color conversion layer CCL may change a wavelength of light. In an embodiment, the first to third sub-pixels SPXL1, SPXL2, and SPXL3 may include light emitting elements LD emitting light of the same color. For example, the first to third sub-pixels SPXL1, SPXL2, and SPXL3 may include light emitting elements LD emitting light of blue. The color conversion layer CCL including color conversion particles is disposed on each of the first to third sub-pixels SPXL1, SPXL2, and SPXL3, so that a full-color image may be displayed.

In an embodiment, in case that the light emitting element LD is a blue light emitting element emitting light of blue, and the first sub-pixel SPXL1 is a red pixel, the first color conversion layer CCL1 may include first color conversion particles (e.g., a first quantum dot QD1) for converting light of blue into light of red. The first quantum dot QD1 may absorb blue light and emit red light by shifting a wavelength of the blue light according to energy transition.

In an embodiment, in case that the light emitting element LD is a blue light emitting element emitting light of blue, and the second sub-pixel SPXL2 is a green pixel, the second color conversion layer CCL2 may include second color conversion particles (e.g., a second quantum dot QD2) for converting light of blue into light of green. The second quantum dot QD2 may absorb blue light and emit green light by shifting a wavelength of the blue light according to energy transition.

The light scattering layer LSL may be provided to efficiently use light of blue, which is emitted from the light emitting element LD. In an example, a light scattering particle SCT of the light scattering layer LSL may include at least one of barium sulfate (BaSO₄), calcium carbonate (CaCO₃), titanium oxide (TiO₂), silicon oxide (SiO₂), aluminum oxide (Al₂O₃), zirconium oxide (ZrO₂), and zinc oxide (ZnO). For example, the light scattering particle SCT may not be disposed only in the third sub-pixel SPXL3, and may be selectively included in the first color conversion layer CCL1 or the second color conversion layer CCL2. In some embodiments, the light scattering particle SCT may be omitted such that the light scattering layer LSL including transparent polymer is provided.

A first capping layer CPL1 may be disposed on the color conversion layer CCL. The first capping layer CPL1 may be provided through the first to third sub-pixels SPXL1, SPXL2, and SPXL3. The first capping layer CPL1 may cover the color conversion layer CCL. The first capping layer CPL1 may prevent the color conversion layer CCL from being damaged or contaminated due to infiltration of an impurity such as moisture or air from the outside.

The first capping layer CPL1 may be an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), and the like.

The optical layer OPL may be disposed on the first capping layer CPL. The optical layer OPL may function to improve light extraction efficiency by reflecting (e.g., totally reflecting) light provided from the color conversion layer CCL. For example, the optical layer OPL may have a refractive index relatively lower than a refractive index of the color conversion layer CCL. For example, the refractive index of the color conversion layer may be in a range of about 1.6 to about 2.0, and the refractive index of the optical layer OPL may be in a range of about 1.1 to about 1.3.

A second capping layer CPL2 may be disposed on the optical layer OPL. The second capping layer CPL2 may be provided throughout the first to third sub-pixels SPXL1, SPXL2, and SPXL3. The second capping layer CPL2 may cover the optical layer OPL. The second capping layer CPL2 may prevent the optical layer OPL from being damaged or contaminated due to infiltration (or permeation) of an impurity such as moisture or air from the outside.

The second capping layer CPL2 may be an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), and the like.

A planarization layer PLL may be disposed on the second capping layer CPL2. The planarization layer PLL may be provided throughout the first to third sub-pixels SPXL1, SPXL2, and SPXL3.

The planarization layer PLL may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the planarization layer PLL may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CFL may be disposed on the planarization layer PLL. The color filter layer CFL may include color filters CF1, CF2, and CF3 which accord with colors of the respective sub-pixels SPXL1, SPXL2, and SPXL3. The color filters CF1, CF2, and CF3 which accord with colors of the respective first to third sub-pixels SPXL1, SPXL2, and SPXL3 are disposed, so that a full-color image may be displayed.

The color filter layer CFL may include a first color filter CF1 disposed in the first sub-pixel SPXL1 to allow light emitted from the first sub-pixel SPXL1 to be selectively transmitted therethrough, a second color filter CF2 disposed in the second sub-pixel SPXL2 to allow light emitted from the second sub-pixel SPXL2 to be selectively transmitted therethrough, and a third color filter CF3 disposed in the third sub-pixel SPXL3 to allow light emitted from the third sub-pixel SPXL3 to be selectively transmitted therethrough.

In an embodiment, the first color filter CF1, the second color filter CF2, and the third color filter CF3 may be respectively a red color filter, a green color filter, and a blue color filter, but embodiments are not limited thereto.

In some embodiments, a light blocking layer BM may be further disposed between the first to third color filters CF1, CF2, and CF3. As described above, in case that the light blocking layer BM is disposed between the first to third color filters CF1, CF2, and CF3, a color mixture defect viewed at the front or side of the display device DD may be prevented. The material of the light blocking layer BM is not limited, and the light blocking layer BM may be formed of various light blocking materials. In an example, the light blocking layer BM may be implemented by stacking the first to third color filters CF1, CF2, and CF3.

An overcoat layer OC may be disposed on the color filter layer CFL. The overcoat layer OC may be disposed throughout the first to third sub-pixels SPXL1, SPXL2, and SPXL3. The overcoat layer OC may cover a lower member including the color filter layer CFL. The overcoat layer OC may prevent moisture or air from infiltrating into the above-described lower member. For example, the overcoat layer OC may protect the above-described lower member from a foreign matter such as dust.

The overcoat layer OC may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the overcoat layer OC may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A film layer OFL may be disposed on the overcoat layer OC. The film layer OFL may reduce or minimize external influence of the display device DD. The film layer OFL may be disposed throughout the first to third sub-pixels SPXL1, SPXL2, and SPXL3. In some embodiments, the film layer OFL may include at least one of a polyethylenephthalate (PET) film, a low reflective film, a polarizing film, and a transmittance controllable film, but embodiments are not limited thereto.

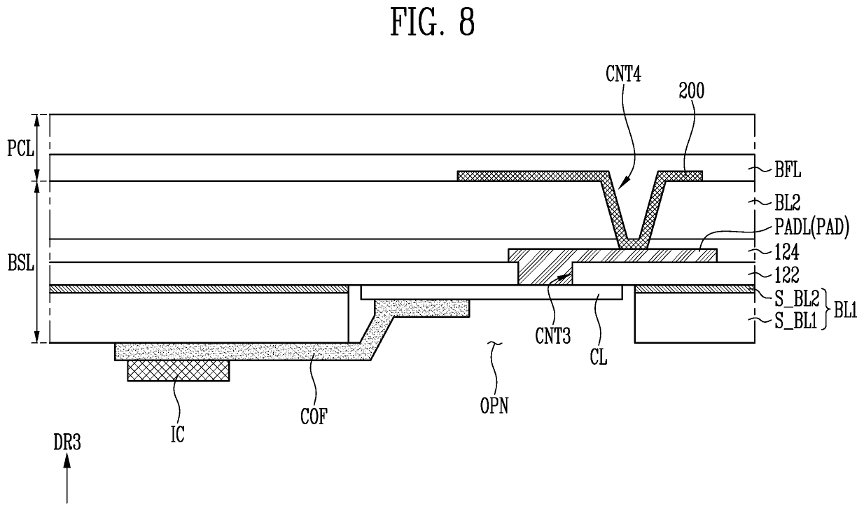

FIG. 8 is a schematic sectional view illustrating an example of a portion of the display device of FIG. 3.

Referring to FIGS. 3, 4, and 8, the base layer BSL of the display device DD may include a first base layer BL1, a first barrier layer 122, a second barrier layer 124, a pad layer PADL, and a second base layer BL2.

In an embodiment, a color of the first base layer BL1 and a color of the second base layer BL2 may be different from each other. For example, a light transmittance of the first base layer BL1 may be lower than a light transmittance of the second base layer BL2.

The first base layer BL1 may provide a base surface on which the chip on film COF is disposed. For example, a surface (e.g., a rear surface or lower surface) of the first base layer BL1 may be adjacent to (or in contact with) the chip on film COF. The first base layer BL1 may include an opening OPN through which the first barrier layer 122 and the pad layer PADL on the top thereof are exposed.

In some embodiments, the first base layer BL1 may be etched in the base layer BSL including the pad layer PADL, so that the pad layer PADL to be connected (e.g., electrically connected) to the chip on film COF is exposed. The first base layer BL1 in contact with the pad layer PADL may be etched (e.g., completely etched) so as to achieve stable electrical connection between the pad layer PADL and the chip on film COF.

However, in a typical process, there is no method capable of checking etching (e.g., etching states or etching conditions) of the first base layer BL1 visually and/or in real time, and it is difficult to determine whether an etching defect of the first base layer BL1 has occurred before an outer lead bonding (OLB) process of connecting the chip on film COF to the base layer BSL.

Therefore, a structure and a process of the display device DD, which are used to simply check the etching of the first base layer BL1 in real time, are required.

In an embodiment, the first base layer BL1 may include a first sub-base layer S_BL1 and a second sub-base layer S_BL2 disposed on the first sub-base layer S_BL1. A light transmittance of the second sub-base layer S_BL2 may be lower than a light transmittance of the first sub-base layer S_BL1. Therefore, the second sub-base layer S_BL2 may have a color darker than a color of the first sub-base layer S_BL1.

In an etching process of the first base layer BL1, the pad layer PADL may be normally (or clearly) exposed only in case that the first and second sub-base layers S_BL1 and S_BL2 corresponding to the opening OPN are removed (e.g., completely removed). In case that the second sub-base layer S_BL2 having a relatively dark color remains with overlapping the pad layer PADL, the color of a conductive material of the pad layer PADL may be distortedly viewed. It may be determined that the etching process of the first base layer BL1 and a corresponding product are defective.

In case that the second sub-base layer S_BL2 is normally (or properly) removed, the color of the conductive material of the pad layer PADL may be relatively clearly viewed. It may be determined that the etching process of the first base layer BL1 has been normally performed, and a subsequent outer lead bonding (OLB) process may be performed.

As described above, in order to determine an etch rate (or etching defect) of the first base layer BL1 in real time, the second sub-base layer S_BL2 in contact with the pad layer PADL may have a light transmittance lower than the light transmittances of the first sub-base layer S_BL1 and the second base layer BL2. For example, the second base layer BL2 may be more transparent than the first sub-base layer S_BL1. For example, the second sub-base layer S_BL2 may be more transparent than the first sub-base layer S_BL1.

In an embodiment, the first sub-base layer S_BL1 and the second sub-base layer S_BL2 may include polyimide. Therefore, the first sub-base layer S_BL1 and the second sub-base layer S_BL2 may have light transparency.

The light transmittances of the first sub-base layer S_BL1 and the second sub-base layer S_BL2 may be adjusted through a change in aromatic group (or functional group) included in polyimide having polymer characteristics, or the like. For example, the light transmittances may be determined through band gap tuning caused by the change in aromatic group (or functional group) included in the polyimide, and the first sub-base layer S_BL1 and the second sub-base layer S_BL2 may have different colors. For example, the second sub-base layer S_BL2 may have a color more yellowish than a color of the first sub-base layer S_BL1.

In an embodiment, a thickness of the second sub-base layer S_BL2 may be about 1/50 or less of a thickness of the first sub-base layer S_BL1. For example, the first sub-base layer S_BL1 may be about 10 μm, and the second sub-base layer S_BL2 may be about 0.1 μm. The second sub-base layer S_BL2 may function to check whether the pad layer PADL is appropriately exposed by formation of the opening OPN, and hence it is necessary for the second sub-base layer S_BL2 to be formed thick in consideration of cost and the like.

In an embodiment, the second sub-base layer S_BL2 may be formed on the first sub-base layer S_BL1 through various types of thin film coating processes. For example, a mask process or the like, which is used to form the second sub-base layer S_BL2, may be omitted.

The first barrier layer 122 may be disposed on the second sub-base layer S_BL2. The first barrier layer 122 may be patterned on the second sub-base layer S_BL2 to have a third contact hole CNT3. The third contact hole CNT3 may overlap the opening OPN.

The first barrier layer 122 may include an inorganic insulating material. For example, the first barrier layer 122 may include at least one selected from the group consisting of amorphous silicon (a-Si), silicon oxide (SiOₓ), silicon nitride (SiNₓ), silicon oxynitride (SiOₓN_{y}), aluminum oxide (AlOₓ), and titanium dioxide (TiOₓ).

The pad layer PADL including a pad PAD may be disposed on the first barrier layer 122. The pad layer PADL may be covered by the second barrier layer 124.

The pad layer PADL may include a conductive material. For example, the pad layer PADL may include copper as a low-resistance conductive material. However, this is merely illustrative, and the pad layer PADL may include at least one selected from the group consisting of copper (Cu), molybdenum (Mo), tungsten (W), aluminum neodymium (AlNd), titanium (Ti), aluminum (Al), silver (Ag), and alloys thereof, or a mixture thereof. In another example, the pad layer PADL may include a transparent conductive material. For example, the transparent conductive material may include ITO, IZO, ZnO, IGZO, ITZO, and the like. The pad layer PADL may be formed in a single-layer structure or a multi-layer structure.

The second barrier layer 124 may be disposed on the first barrier layer 122, and cover at least a portion of the pad layer PADL. The second barrier layer 124 may include an inorganic insulating material. For example, the second barrier layer 124 may include at least one selected from the group consisting of amorphous silicon (a-Si), silicon oxide (SiOₓ), silicon nitride (SiNₓ), silicon oxynitride (SiOₓN_{y}), aluminum oxide (AlOₓ), and titanium dioxide (TiOₓ).

The first barrier layer 122 and the second barrier layer 124 may be formed of an inorganic insulating material so as to stably form and dispose the first base layer BL1, the second base layer BL2, and the pad layer PADL. In an embodiment, the second barrier layer 124 may have a structure in which a layer including silicon nitride (SiNₓ) and a layer including silicon oxynitride (SiOₓN_{y}) are alternately disposed. The first barrier layer 122 may have a structure in which a layer including amorphous silicon (a-Si) and a layer including silicon oxide (SiOₓ) are alternately disposed. However, embodiments are not limited thereto.

The second base layer BL2 may provide a base surface on which the pixel circuit layer PCL is disposed. In an embodiment, a surface (e.g., top surface or upper surface) of the second base layer BL2 may be in contact with the pixel circuit layer PCL, and another surface (e.g., rear surface or lower surface) of the second base layer BL2 may be in contact with the second barrier layer 124. The second base layer BL2 may include transparent polyimide. In some embodiments, the second base layer BL2 may have a thickness thinner than a thickness of the first base layer BL1. For example, the thickness of the second base layer BL2 may be about 5.8 μm.

The lower connection electrode 200 may be disposed on the second base layer BL2. In an embodiment, the lower connection electrode 200 may be connected (e.g., electrically and physically connected) to the pad layer PADL through a fourth contact hole CNT4 penetrating the second base layer BL2 and the second barrier layer 124. For example, the lower connection electrode 200 may be connected (e.g., electrically connected) to the pad layer PADL by penetrating (or passing through) the second base layer BL2. A signal (e.g., a data signal) supplied through the pad layer PADL may be supplied to the lower connection electrode 200. In an embodiment, as described with reference to FIG. 6, the lower connection electrode 200 may be connected (e.g., electrically connected) to the data line DL thereabove through the data contact hole DCNT.

The lower connection electrode 200 may include a conductive material. For example, the lower connection electrode 200 may include at least one selected from the group consisting of copper (Cu), molybdenum (Mo), tungsten (W), aluminum neodymium (AlNd), titanium (Ti), aluminum (Al), silver (Ag), and alloys thereof, or a mixture thereof. In another example, the lower connection electrode 200 may include a transparent conductive material. For example, the transparent conductive material may include ITO, IZO, ZnO, IGZO, ITZO, and the like. The lower connection electrode 200 may be formed in a single-layer structure or a multi-layer structure.

In an embodiment, the first base layer BL1 forms the opening OPN, and portions of the first barrier layer 122 and the pad layer PADL may be exposed. A connection line CL may be disposed on a rear surface (or lower surface) of the first base layer BL1 to be in contact with the exposed pad layer PADL. For example, the connection line CL may be formed in the opening OPN. The connection line CL may connect (e.g., electrically connect) the pad layer PADL and the chip on film COF to each other.

The connection line CL may include a conductive material. For example, the connection line CL may include at least one selected from the group consisting of copper (Cu), molybdenum (Mo), tungsten (W), aluminum neodymium (AlNd), titanium (Ti), aluminum (Al), silver (Ag), and alloys thereof, or a mixture thereof. In another example, the connection line CL may include a transparent conductive material. For example, the transparent conductive material may include ITO, IZO, ZnO, IGZO, ITZO, and the like. The connection line CL may be formed in a single-layer structure or a multi-layer structure.

A portion of the chip on film COF may be disposed in the opening OPN to be connected (e.g., electrically connected) to the connection line CL. Another portion of the chip on film COF may extend to the outside of the opening OPN to be disposed on the rear surface (or lower surface) of the base layer BSL.

The driving chip IC may be disposed on a surface of the chip on film COF or be mounted in a partial area of the chip on film COF. The driving chip IC may function as the data driver and/or the timing controller, and be connected (e.g., electrically connected) to the chip on film COF. For example, a data signal output from the driving chip IC may be supplied to the data line DL through the chip on film COF, the connection line CL, the pad PAD, and the lower connection electrode 200.

As described above, the display device DD in accordance with the embodiments may include the first base layer BL1 (e.g., the second sub-base layer S_BL2) having a relatively low light transmittance on the bottom of the pad layer PADL so as to check (or sense) in real time whether an etching defect has occurred in an etching process for forming the opening OPN of the first base layer BL1. Thus, a process defect in a process of forming the opening OPN before an outer lead bonding (OLB) process may be readily checked or sensed, and a process yield may be improved.

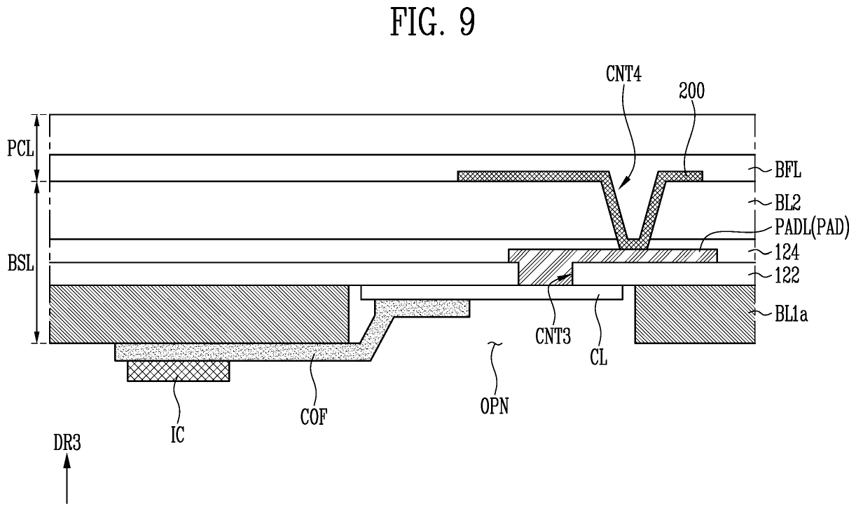

FIG. 9 is a schematic sectional view illustrating an example of the portion of the display device of FIG. 3.

In FIG. 9, components identical to those described with reference to FIG. 8 are designated by like reference numerals, and redundant descriptions will be omitted for descriptive convenience.

Referring to FIGS. 3, 4, and 9, the base layer BSL of the display device DD may include a first base layer BL1a, a first barrier layer 122, a second barrier layer 124, a pad layer PADL, and a second base layer BL2.

In an embodiment, a color of the first base layer BL1a may be different from a color of the second base layer BL2. For example, the first base layer BL1a may have a color darker than a color of the second base layer BL2. A color viewed (or photographed) in a state in which the colored first base layer BL1a and the exposed pad layer PADL overlap each other is different from an original color of the pad layer PADL, and therefore, the first base layer BL1a may have a relatively dark color.

In an embodiment, the first base layer BL1a and the second base layer BL2 may include polyimide. The first base layer BL1a and the second base layer BL2 may include polyimides having different compositions, and light transmittances of the first base layer BL1a and the second base layer BL2 may be different from each other.

The first base layer BL1a in accordance with the embodiment of FIG. 9 may include a single-layer polyimide layer, so that it is advantageous in terms of cost and time of a process of forming the first base layer BL1a, as compared with the embodiment of FIG. 8.

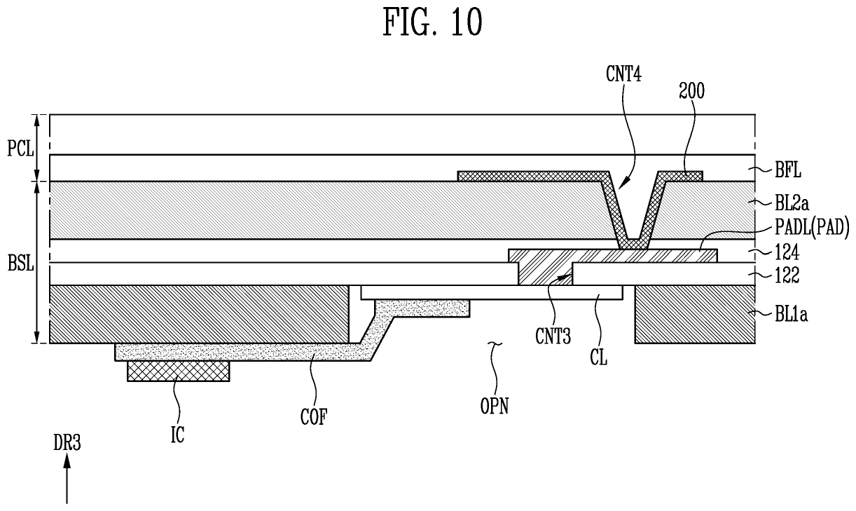

FIG. 10 is a schematic sectional view illustrating an example of the portion of the display device of FIG. 3.

In FIG. 10, components identical to those described with reference to FIGS. 8 and 9 are designated by like reference numerals, and redundant descriptions will be omitted for descriptive convenience.

Referring to FIGS. 3, 4, and 10, the base layer BSL of the display device DD may include a first base layer BL1a, a first barrier layer 122, a second barrier layer 124, a pad layer PADL, and a second base layer BL2a.

The first base layer BL1a and the second base layer BL2a may include polyimide. The first base layer BL1a may have a color darker than a color of the second base layer BL2a. For example, a light transmittance of the first base layer BL1a may be lower than a light transmittance of the second base layer BL2a.

In an embodiment, the second base layer BL2a may be colored and have a low light transmittance. Accordingly, light which is emitted toward a lower portion (e.g., in the opposite direction of the third direction DR3) in the upper display element layer DPL (see FIG. 6) and passes through a lower portion of the second base layer BL2a may be blocked or reduced.

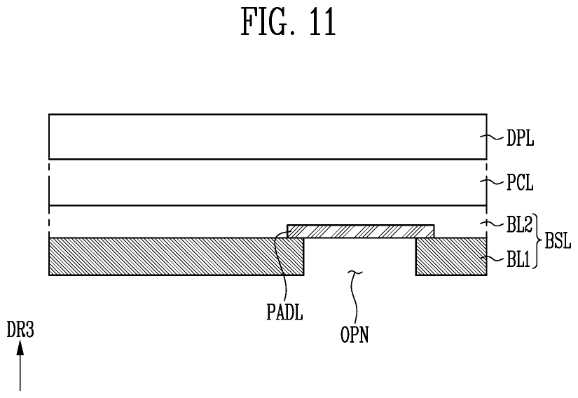

FIGS. 11 to 21 are views illustrating a method of manufacturing the display device in accordance with embodiments.

In FIGS. 11 to 21, descriptions of portions overlapping those associated with the manufacturing method described with reference to FIGS. 8 to 10 will be omitted.

Referring to FIGS. 9 and 11 to 21, the method of manufacturing the display device may include forming a pad layer PADL on a first base layer BL1, patterning a second base layer BL2 on the pad layer PADL, forming a pixel circuit layer PCL on the second base layer BL2, and forming a display element layer DPL on the pixel circuit layer PCL.

FIG. 11 schematically illustrates a sectional view of the display device DD in which the base layer BSL including an opening OPN exposing the pad layer PADL, the pixel circuit layer PCL, and the display element layer DPL are sequentially stacked. In an embodiment, a light transmittance of the first base layer BL1 may be lower than a light transmittance of the second base layer BL2. For example, a color of the first base layer BL1 may be darker than a color of the second base layer BL2.

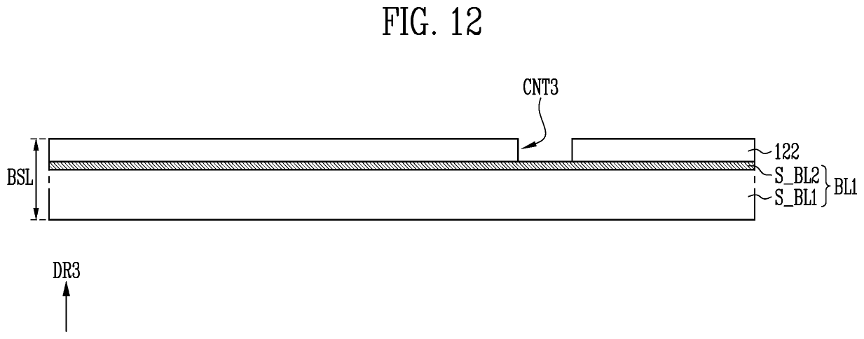

FIGS. 12 to 16 illustrate an example of the method of manufacturing the display device including the first base layer BL1 described with reference to FIG. 8. However, this is merely illustrative, and the display device may be replaced with the stacked structure of FIG. 9 or 10 according to a configuration of the first base layer BL1.

In an embodiment, as shown in FIG. 12, a second sub-base layer S_BL2 may be coated on a first sub-base layer S_BL1. The second sub-base layer S_BL2 may be formed through various thin film coating processes (e.g., a slit coating process, and the like).

The second sub-base layer S_BL2 may have a light transmittance lower than a light transmittance of the first sub-base layer S_BL1. The first sub-base layer S_BL1 and the second sub-base layer S_BL2 may include polyimide. The light transmittances of the first sub-base layer S_BL1 and the second sub-base layer S_BL2 may be controlled differently from each other through band gap tuning of polyimide having polymer characteristics.

Subsequently, a first barrier layer 122 may be formed on the second sub-base layer S_BL2. The first barrier layer 122 may be patterned to include a contact hole (e.g., a third contact hole CNT3). For example, the first barrier layer 122 may be formed through patterning using a mask after an inorganic layer is deposited. However, this is merely illustrative, and the method of forming the first barrier layer 122 is not limited thereto.

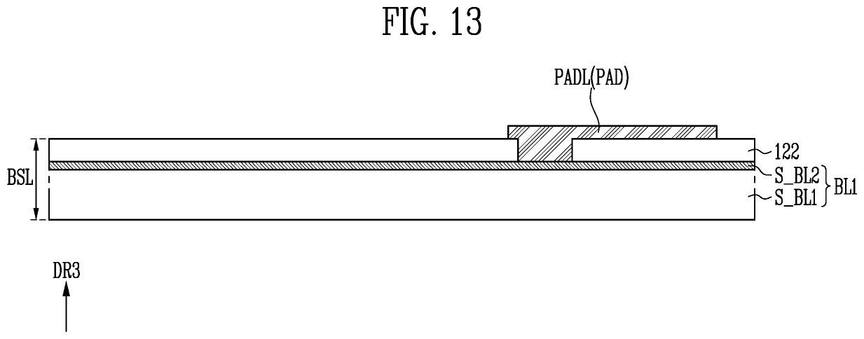

Subsequently, as shown in FIG. 13, a pad layer PADL including pads PAD may be patterned on the first barrier layer 122. For example, the pad layer PADL may be formed through patterning using a mask after a metal layer is deposited. However, this is merely illustrative, and the method of forming the pad layer PADL is not limited thereto.

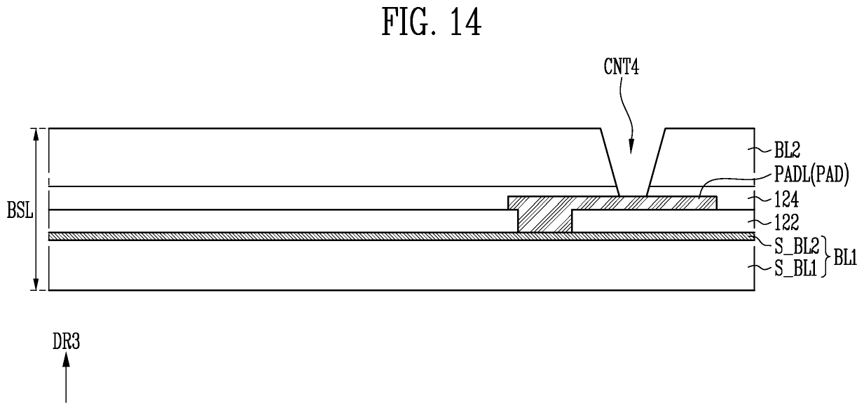

Subsequently, as shown in FIG. 14, a second barrier layer 124 covering the pad layer PADL may be formed on the first barrier layer 122, and a second base layer BL2 may be formed on the second barrier layer 124. For example, the second barrier layer 124 and the second base layer BL2 may be patterned, thereby forming a contact hole (e.g., a fourth contact hole CNT4) and exposing a portion of a top surface of the pad layer PADL.

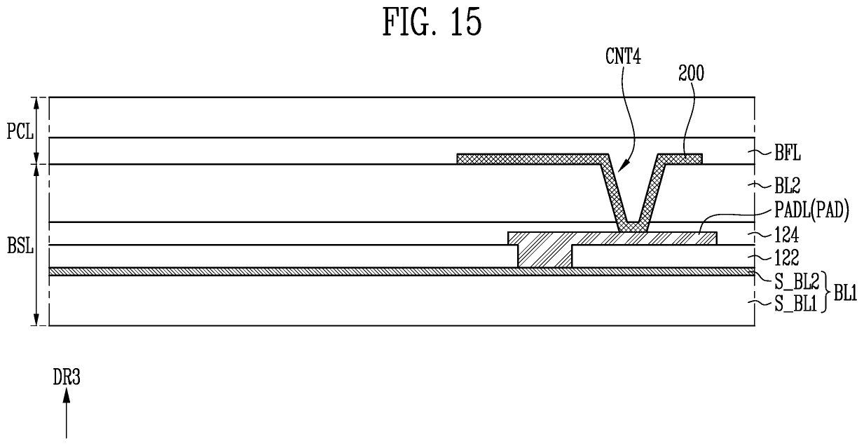

Subsequently, as shown in FIG. 15, a lower connection electrode 200 as a component of the pixel circuit layer PCL may be formed on the second base layer BL2. The lower connection electrode 200 may be connected (e.g., electrically connected) to the pad PAD of the pad layer PADL through the fourth contact hole CNT4. For example, the lower connection electrode 200 may be connected (e.g., electrically connected) to the pad PAD of the pad layer PADL by penetrating (or passing through) the second base layer BL2.

In an embodiment, the pixel circuit layer PCL (as described with reference to FIG. 6) including a buffer layer BFL covering the lower connection electrode 200 may be formed on the second base layer BL2.

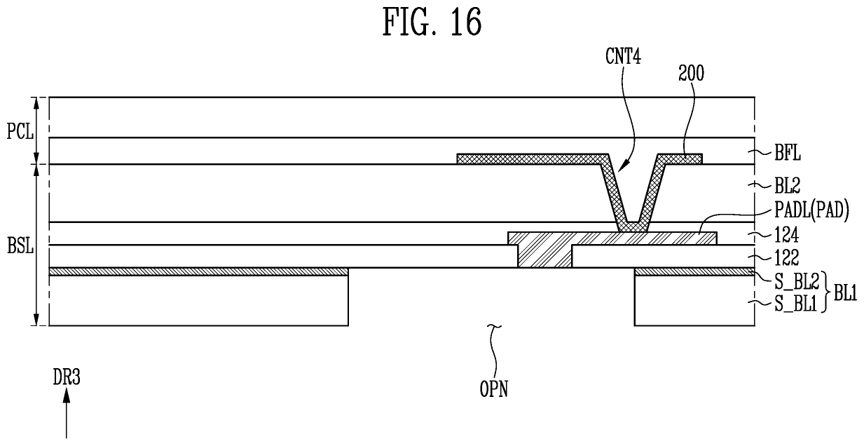

Subsequently, as shown in FIG. 16, a portion of the first base layer BL1 may be removed to expose a rear surface (or lower surface) of the pad layer PADL from the first base layer BL1. In an embodiment, the first base layer BL1 (e.g., the first sub-base layer S_BL1 and the second sub-base layer S_BL2) may be removed (or etched) through at least one process selected from a laser etching process and an atmospheric pressure plasma treatment, and an opening OPN may be formed.

As described above, the pad layer PADL and a chip on film (e.g., COF of FIG. 9) may be connected (e.g., electrically stably connected) to each other only in case that the whole of the first base layer BL1 overlapping the pad layer PADL is removed and in case that the rear surface (or lower surface) of the pad layer PADL is exposed (e.g., completely exposed). FIG. 16 illustrates an example in which the whole of the first base layer BL1 (e.g., the first sub-base layer S_BL1 and the second sub-base layer S_BL2) corresponding to the opening OPN is removed.

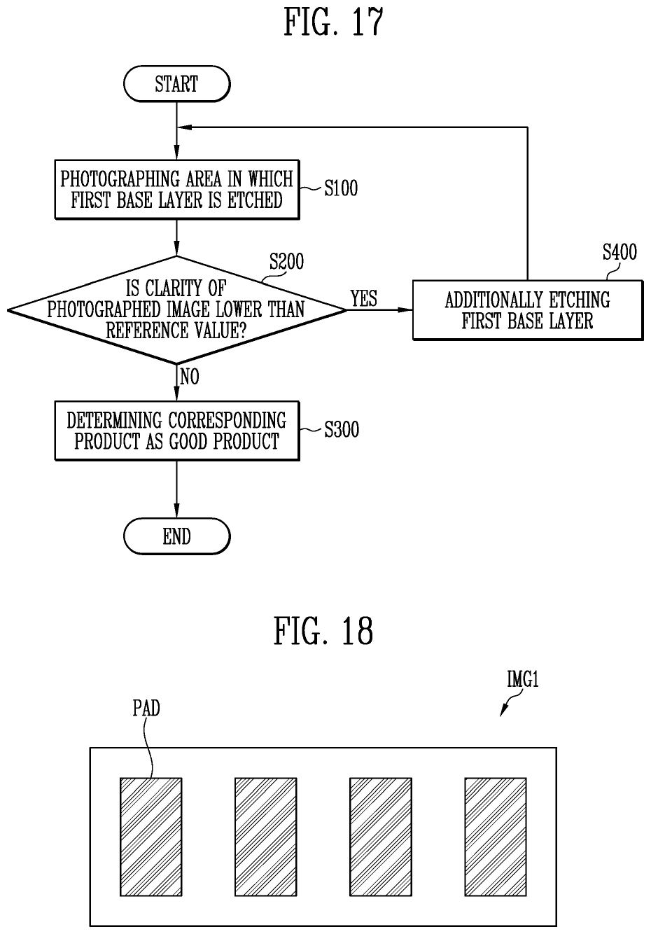

In an embodiment, it may be determined whether the etching process is completed by photographing an area in which the first base layer BL1 is etched (or by obtaining an image of an etching area in which the first base layer BL1 is etched), using a camera or the like. For example, as shown in FIG. 17, the area (e.g., the opening OPN), in which the first base layer BL1 is etched, may be photographed (S100), and a photographed image and a reference value (or reference image) may be compared (S200). For example, at least one of clarity, chroma, and color of the pad PAD of the photographed image may be compared with a reference value of a characteristic corresponding thereto. The reference value may include at least one of a clarity reference value, a chroma reference value, and a color reference value.

For example, in case that the clarity and/or chroma of the pad layer PADL (or the pad PAD) of the photographed image is not lower than the reference value, it may be determined that the etching process of the first base layer BL1 is normally (or properly) performed, and a corresponding display device may be determined as a good product (S300). The etching process of the first base layer BL1 may be ended. For example, an outer lead bonding (OLB) process for connecting (e.g., electrically connecting) the chip on film COF or the like to the pad layer PADL may be performed.

In case that the clarity and/or chroma of the pad layer PADL (or the pad PAD) of the photographed image is lower than the reference value, it may be determined that the second sub-base layer S_BL2 remains (or it may be determined that the etching process is defective). The first base layer BL1 including the second sub-base layer S_BL2 may be additionally etched (S400), or a corresponding product may be determined as a bad product.

In an embodiment, the photographing of the image of the opening ONP and the determining of whether the corresponding product is the good product (or whether the etching process is completed) may be performed in real time during the etching process of the first base layer BL1.

For example, FIG. 18 illustrates an example of a first image IMG1 photographed in case that the first base layer BL1 is etched (e.g., completely etched). As shown in FIG. 18, the second sub-base layer S_BL2 having a low light transmittance is removed (e.g., completely removed) from the exposed pad PAD, and therefore, the pad PAD in the first image IMG1 may be expressed relatively clearly (or with high chroma).

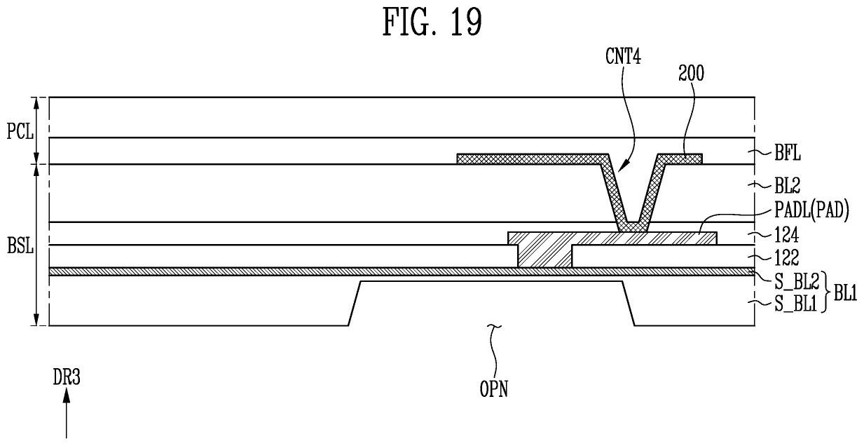

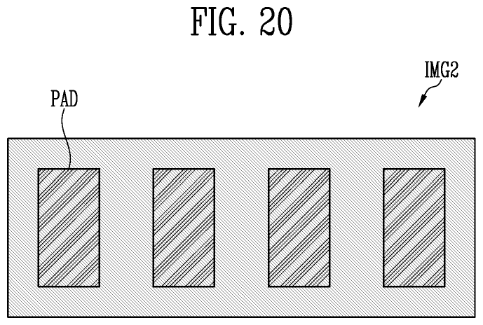

FIG. 19 illustrates an example in which the opening OPN of the first base layer BL1 is incompletely etched. For example, a least a portion of the second sub-base layer S_BL2 may remain on the exposed pad PAD. For example, a portion of the first sub-base layer S_BL1 may also remain on the exposed pad PAD.

FIG. 20 illustrates an example of a second image IMG2 photographed in case that the first base layer BL1 is incompletely etched. As shown in FIG. 20, since the second sub-base layer S_BL2 having a low light transmittance overlaps the exposed pad PAD, the pad PAD in the second image IMG2 has low clarity and low chroma as compared with the first image and may be expressed unclearly (or blurredly).

It may be readily determined whether the etched portion of the first base layer BL1 has a good quality, based on the photographed image, without addition of a separate process and an inspection time.

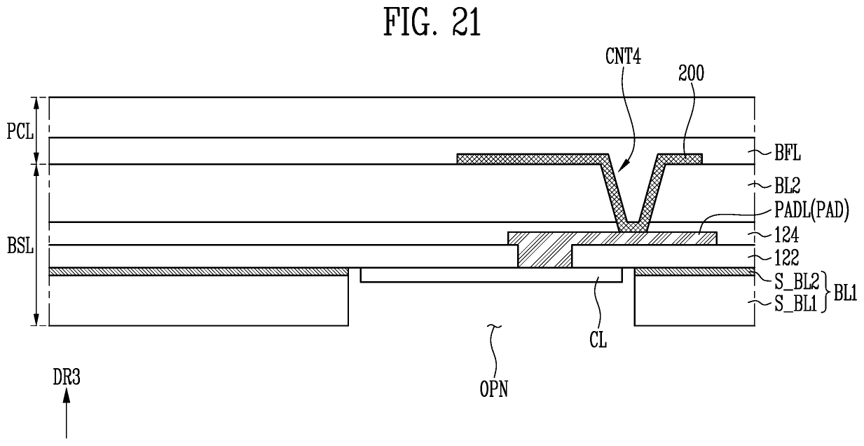

In an embodiment, after the step S300, a connection line CL in contact with the exposed pad layer PADL may be patterned as shown in FIG. 21. The connection line CL may include a conductive material, and be formed in the opening OPN.

Subsequently, as shown in FIG. 8, the chip on film COF connected (e.g., electronically connected) to the connection line CL may be disposed on a surface (e.g., rear surface or lower surface) of the first base layer BL1 (e.g., the first sub-base layer S_BL1). In some embodiments, the driving chip IC may be disposed on the chip on film COF, or be mounted at a portion of the chip on film COF (e.g., performance of an outer lead bonding (OLB) process).

As described above, in the display device and the method of manufacturing the same in accordance with the embodiments, the first base layer BL1 (e.g., the second sub-base layer S_BL2) having a relatively low light transmittance may be disposed on the bottom of the pad layer PADL. Thus, it may be readily determined in real time whether an etched portion of the first base layer BL1 in an etching process for forming the opening OPN has a good quality, without addition of a separate process (e.g., inspection phase) and inspection time. Accordingly, a process defect in the process of forming the opening OPN before the outer lead bonding (OLB) process may be readily checked or sensed, and a process yield may be improved.

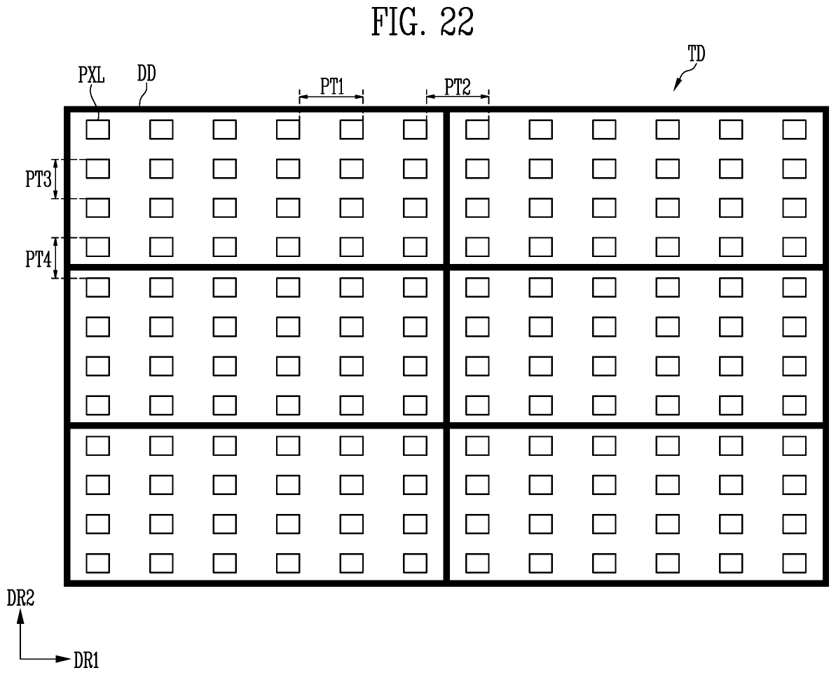

FIG. 22 is a schematic plan view illustrating a tiled display device including the display device in accordance with embodiments.

Referring to FIG. 22, the tiled display device TD (or multi-panel display device) may include display devices DD.

The tiled display device TD may be formed by connecting two or more display devices DD to each other. Although a case where 2×3 display devices DD are connected to each other is illustrated in FIG. 22, the arrangement and number of display devices DD included in the tiled display device TD are not limited thereto.

Each display device DD may include pixels PXL. In an embodiment, the display devices described with reference to FIGS. 1 to 21 may be included as a configuration of the tiled display device TD.

A first distance (e.g., a pitch) PT1 between the pixels PXL in the first direction DR1 in the display device DD may be substantially uniform. For example, the pixels PXL may be disposed at an equal distance of the first distance PT1 with respect to the first direction DR1. A distance between closest pixels PXL of adjacent display devices DD in the first direction DR1 may be defined as a second distance PT2. The first direction DR1 may be a lateral direction, and the second direction DR2 may be a longitudinal direction.

In an embodiment, the first distance PT1 and the second distance PT2 may be designed to be substantially equal to each other.

A distance between the pixels PXL in the second direction DR2 in the display device DD may be defined as a third distance PT3, and a distance between closest pixels PXL of adjacent display devices DD in the second direction DR2 may be defined as a fourth distance PT4.

In an embodiment, the third distance PT3 and the fourth distance PT4 may be designed to be substantially equal to each other.

However, this is merely illustrative, and the distance (pitch) between the pixels PXL is not limited thereto.

In an embodiment, as described with reference to FIG. 4 and the like, a driver/driving circuit for driving the pixels PXL may be disposed on a rear surface of each display device DD with overlapping the display area DA. Thus, a bezel (e.g., dead space, or peripheral area) may be minimized.

In the display device and the method of manufacturing the same in accordance with the disclosure, a first base layer (e.g., a second sub-base layer) having a relatively low light transmittance may be disposed on the bottom of a pad layer. Thus, it may be readily determined in real time whether an etched portion of the first base layer in an etching process for forming an opening has a good quality, without addition of a separate process (e.g., inspection phase) and inspection time. Accordingly, a process defect in the process of forming the opening before an outer lead bonding (OLB) process may be readily checked, and a process yield may be improved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a first base layer including opening;
a pad layer disposed on the first base layer, the pad layer overlapping the opening;
a second base layer disposed on the pad layer;
a pixel circuit layer disposed on the second base layer; and
light emitting elements disposed on the pixel circuit layer, the light emitting elements connected to the pixel circuit layer and included in pixels,
wherein a color of the first base layer is different from a color of the second base layer.

2. The display device of claim 1, wherein
the first base layer includes:
a first sub-base layer; and
a second sub-base layer disposed on the first sub-base layer, the second sub-base layer being closer to the pad layer than the first sub-base layer, and
a light transmittance of the second sub-base layer is lower than a light transmittance of the first sub-base layer.

3. The display device of claim 2, wherein the first sub-base layer, the second sub-base layer, and the second base layer include polyimide.

4. The display device of claim 3, wherein the second sub-base layer has a color darker than colors of the first sub-base layer and the second base layer.

5. The display device of claim 4, wherein a thickness of the second sub-base layer is about 1/50 or less of a thickness of the first sub-base layer.

6. The display device of claim 1, wherein the first base layer and the second base layer include a same material.

7. The display device of claim 6, wherein a light transmittance of the first base layer is lower than a light transmittance of the second base layer.

8. The display device of claim 7, wherein the first base layer and the second base layer include polyimide.

9. The display device of claim 1, further comprising:
a chip on film (COF) electrically connected to the pad layer, the chip on film (COF) extending on a surface of the first base layer; and
a driving chip disposed on the chip on film (COF), the driving chip that provides a signal to the pixel circuit layer,
wherein, in a plan view, the chip on film (COF) and the driving chip overlap a display area in which the pixels are disposed.

10. The display device of claim 9, wherein the pixel circuit layer includes a lower connection electrode disposed on the second base layer, the lower connection electrode connected to the pad layer and penetrating the second base layer.

11. The display device of claim 10, wherein the lower connection electrode is electrically connected to a signal line of the pixel circuit layer through a contact hole.

12. The display device of claim 9, further comprising:
a first barrier layer disposed directly on the first base layer, the first barrier layer having a contact hole overlapping the opening of the first base layer; and
a second barrier layer disposed between the first barrier layer and the second base layer, wherein
the pad layer is disposed between the first barrier layer and the second barrier layer, and
the pad layer is electrically connected to the chip on film (COF) through the contact hole of the first barrier layer.

13. The display device of claim 12, wherein the first barrier layer and the second barrier layer include an inorganic insulating material.

14. A method of manufacturing a display device, the method comprising:
forming a pad layer on a first base layer;
forming a second base layer including a contact hole on the first base layer;
forming, on the second base layer, a pixel circuit layer including a lower connection electrode in contact with the pad layer through the contact hole of the second base layer;
forming a display element layer including light emitting elements on the pixel circuit layer; and
removing a portion of the first base layer to expose the pad layer,
wherein a color of the first base layer is different from a color of the second base layer.

15. The method of claim 14, wherein
the forming of the pad layer on the first base layer includes:
coating, on a first sub-base layer, a second sub-base layer having a light transmittance lower than a light transmittance of the first sub-base layer;
forming a first barrier layer on the second sub-base layer;
patterning the pad layer on the first barrier layer; and
forming a second barrier layer covering the pad layer on the first barrier layer, and
the first sub-base layer, the second sub-base layer, and the second base layer include polyimide.

16. The method of claim 15, wherein the second sub-base layer has a color darker than colors of the first sub-base layer and the second base layer.

17. The method of claim 16, wherein the removing of the portion of the first base layer includes:
etching the first base layer overlapping the pad layer by using at least one of a laser etching process and an atmospheric pressure plasma treatment; and
determining whether the etching of the first base layer is completed based on an image of an etched area in which the first base layer is etched.

18. The method of claim 17, wherein the determining of whether the the etching of the first base layer is completed includes:
comparing the image of the etching area with a reference value;
additionally etching the first base layer in case that clarity of a pad layer of the image of the etched area is lower than the reference value; and
ending the etching of the first base layer in case that the clarity of the pad layer of the image of the etched area is not lower than the reference value.

19. The method of claim 14, further comprising:
forming a connection line in contact with the pad layer; and
disposing a chip on film (COF) electrically connected to the connection line on a surface of the first base layer.

20. The method of claim 19, wherein the chip on film (COF) overlaps a display area in which pixels including the light emitting elements are disposed.
